(19) United States
(12) Patent Application Publication
(10) Pub. No.: US 2008/0087456 A1
(43) Pub. Date: Apr. 17, 2008

(54) CIRCUIT BOARD ASSEMBLIES WITH COMBINED FLUID-CONTAINING HEATSPREADER-GROUND PLANE AND METHODS THEREFOR

(75) Inventor: Franz Michael Schuette, Colorado Springs, CO (US)

Correspondence Address: HARTMAN & HARTMAN, P.C., 552 EAST 700 NORTH, VALPARAISO, IN, 46383, US

(73) Assignee: ONSCREEN TECHNOLOGIES, INC., Portland, OR (US)

(21) Appl. No.: 11/871,498

(22) Filed: Oct. 12, 2007

Related U.S. Application Data
(60) Provisional application No. 60/829,325, filed on Oct. 13, 2006.

(51) Int. Cl. H05K 1/00; H05K 3/00

(52) U.S. Cl. 174/252; 29/829

(57) ABSTRACT

Circuit board assemblies and methods that employ integrated heatspreaders to cool the assemblies and serve as electrical ground planes for the assemblies. Such a circuit board assembly includes a substrate having at least one circuit device on at least a first surface thereof and an electrical ground plane. The circuit device has a first set of solder connections electrically connected to the electrical ground plane and a second set of solder connections electrically connected to power and signal traces on the first surface of the substrate. The assembly further includes a heatspreader embedded in the substrate and defining an electrical element of the electrical ground plane as a result of being electrically connected to the first set of solder connections. The heatspreader is configured as a plate-mesh-plate laminate that defines a cavity containing a fluid for transferring heat from the circuit device.

### CROSS REFERENCE TO RELATED APPLICATIONS

This application claims the benefit of U.S. Provisional Application No. 60/829,325, filed Oct. 13, 2006, the contents of which are incorporated herein by reference.

### BACKGROUND OF THE INVENTION

The present invention generally relates to circuit board assemblies. More particularly, this invention relates to circuit board assemblies with enhanced thermal management capabilities.

With the evolution of electronic devices, integrated circuits (ICs) have become increasingly condensed with respect to overall power density. Contributing factors are the migration to smaller design processes that shrink the physical dimensions of devices, including transistors and capacitors, as well as metal layer interconnects. In addition, the power consumption linearly follows the number of switching events, which, in turn, is a direct function of the operating frequency. The result is the ubiquity of ICs that feature transistor counts at orders of magnitude higher than their predecessors, with operating frequencies at only a fraction of the footprint of their predecessors. Though a portion of the increased power demand can be offset by lower operating voltages, from the above it is evident that lower voltages can only be a partial remedy for increasing power density.

Thermal management of ICs has evolved greatly over the past few years. Whereas a simple metal plate integrated into an IC package previously sufficed, current ICs are finding more and more sophisticated methods to offload heat. Historically, ICs were packaged with the active silicon of the chip facing down and cooling applied primarily to the backside of the chip substrate. This approach incurs the thermal resistance of the substrate, resulting in reduced heat dissipation since the substrate behaves as a heat barrier to at least some degree. An improved solution was the development of flip-chip designs in which the active die faces up and can be in direct contact with a heatspreader.

Further improvements in cooling techniques have been achieved with factory-preinstalled heat slugs over the die. This step solves two problems, namely, it eliminates the risk of accidental damage to the surface of the chip during mounting and, more importantly, by using a low-temperature solder to attach the heat slug, a highly efficient heat transfer path with increased surface area can be established. The heat slug can then be interfaced with relative ease to any secondary cooling device using standard thermal interface materials.

Heatspreaders that contain a cooling fluid have also been proposed, as taught in commonly-assigned U.S. Pat. No. 7,219,715 to Popovich and commonly-assigned U.S. patent application Ser. No. 11/861,810 to Schuette, the contents of which are incorporated herein by reference. The cooling fluids of Popovich and Schuette flow through microchannels formed by interstices of a woven metal screen or mesh sandwiched between two foils or plates. Popovich discloses an open fluid cooling system in which the cooling fluid is in direct contact with an integrated circuit device, whereas Schuette discloses a fully-sealed, self-contained fluid cooling system in which thermal energy is initially absorbed by the foil nearest a heat source, propagated through the mesh into a cooling fluid within the microchannels, and then removed by displacement of the fluid. At a distance from the heat source, the thermal transfer process is reversed, namely, the heat absorbed by the fluid is transferred to the mesh and finally to the second foil for dissipation into the environment.

Other types of microchannels for coolant fluids have also been known for some time, as evidenced by U.S. Pat. No. 4,450,472 to Tuckerman et al. The preferred embodiment featured in this patent integrated microchannels into the die of the microchip to be cooled and coolant chambers. U.S. Pat. No. 5,801,442 also describes a similar approach. Still other approaches have focused on the combined use of coolant phase change (condensation) and microchannels, an example of which is U.S. Pat. No. 6,812,563. U.S. Pat. No. 6,934,154 describes a similar two-phase approach including an enhanced interface between an IC die and a heatspreader based on a flip-chip design and the use of a thermal interface material. U.S. Pat. Nos. 6,991,024, 6,942,018, and 6,785,134 describe electroosmotic pump mechanisms and vertical channels for increased heat transfer efficiencies. Variations of microchannel designs include vertical stacking of different orientational channel blocks as described in U.S. Pat. No. 6,675,875, flexible microchannel designs using patterned polyimide sheets as described in U.S. Pat. No. 6,904,966, and integrated heating/cooling pads for thermal regulation as described in U.S. Pat. No. 6,692,700.

Additional efforts have been directed to the manufacturing of microchannels. U.S. Pat. Nos. 7,000,684, 6,793,831, 6,672,502, and 6,989,134 are representative examples, and disclose forming microchannels by sawing, stamping, crosscutting, laser drilling, soft lithography, injection molding, electrodeposition, microetching, photoablation chemical micromachining, electrochemical micromachining, through-mask electrochemical micromachining, plasma etching, water jet, abrasive water jet, electrodischarge machining (EDM), pressing, folding, twisting, stretching, shrinking, deforming, and combinations thereof. All of these methods, however, share the drawback of requiring a more or less elaborate and expensive manufacturing process.

A parallel development has occurred in the electrical interfacing of ICs with the substrates to which they are mounted. Most older ICs used edge pins to receive power as well as for communicating with the electrical system on a substrate, such as a printed circuit board (PCB). Exemplary designs were PDIP, QFP, SOP, and TSOP, among others, wherein the die is interfaced through bond wires to a lead frame, with the latter extending to form lateral feet that are soldered to a circuit board. Advantages of this design include the relative ease of mounting as well as the facilitation of potential manual reworks. Recently, the trend has moved to a more sophisticated interfacing scheme known as a ball grid array (BGA), in which IC chips are housed in a package with contacts distributed on one of its surfaces for use as interconnects to a conductor pattern on a substrate. An important factor to consider in this context is the fact that in almost every case, a large number of contacts is dedicated to providing distributed power and ground to the IC. In particular, power and ground buses of BGAs are typically relatively solid structures as opposed to the much finer signal traces. As a result, the ground plane of a circuit board is capable of absorbing heat from its ICs through the solder ball connections of the ICs. Some circuit board designs, especially in the field of lower power devices such as memory modules, specifically take advantage of augmented copper ground planes to transfer heat from ICs to blank areas of the circuit board. In this case, the ground plane is typically located within an inner layer of the circuit board to avoid interference with signal routing through the circuit board. Inherently, this has the disadvantage of encapsulating the heatspreader and, as a result, a connection must be provided to a terminal heatspreader external to the circuit board, typically through the use of vias. Furthermore, heat conductance is often limited by the very small cross-sectional area typical of ground planes. Consequently, a ground plane used as an internal heatspreader within a circuit board is rather limited in its ability to dissipate heat generated by ICs on the circuit board. While thermal conduction through a ground plane used as an internal heatspreader can be enhanced by increasing the thickness of the ground plane, doing so comes at a severe cost of material and weight disadvantage, since a highly electrical-conductive metal such as copper or silver must normally be used as the material for ground planes. In view of these limitations, there is a continuing need for circuit board assemblies with enhanced thermal management capabilities.

### BRIEF SUMMARY OF THE INVENTION

The present invention provides circuit board assemblies and methods that employ integrated heatspreaders to cool the assemblies and serve as electrical ground planes for the assemblies.

According to a first aspect of the invention, a circuit board assembly includes a circuit board substrate having at least one circuit device on at least a first surface thereof and an electrical ground plane. The circuit device has a first set of solder connections electrically connected to the electrical ground plane and a second set of solder connections electrically connected to power and signal traces on the first surface of the substrate. The assembly further includes a heatspreader embedded in the substrate and defining an electrical element of the electrical ground plane as a result of being electrically connected to the first set of solder connections. The heatspreader is configured as a plate-mesh-plate laminate that defines a cavity containing a fluid for transferring heat from the circuit device.

According to a second aspect of the invention, a method is provided for combining an electrical ground plane of a circuit board substrate with heat dissipation from a circuit device on a first surface of the substrate. The method entails fabricating the substrate to have an embedded heatspreader comprising a plate-mesh-plate laminate filled with coolant fluid.

In view of the above, heatspreaders employed by this invention are sealed, fluid-filled laminates integrated into a circuit board assembly to concurrently act as an electrical ground plane and a thermal management device, by which the fluid within the heatspreader transfers heat away from a heat source on the circuit board substrate. The heat source may be an IC chip or package mounted to the circuit board substrate, and the heat path from the heat source to the heatspreader may include solder connections of an IC package or IC die that are part of the ground bus of the circuit board. As such, the heatspreader also serves as the electrical ground plane of the circuit board assembly.

The fluid within the heatspreader is preferably contained in microchannels defined by a screen or mesh within the cavity, which is preferably defined between two foils or plates. The fluid may flow through the microchannels by natural convection or forced convention, the latter of which includes forced flow with a pump. Because the heatspreader carries current as a result of being part of the ground plane of the circuit board, the current can be used to move an ionically-charged fluid through the microchannels by electroosmotic flow.

The heatspreader can be located at or beneath a surface of a circuit board substrate and locally restricted to exclude power and signaling traces. Alternatively, the heatspreader can be located in a layer different from those containing signals and power traces, in which case the heatspreader is preferably situated within an internal layer of the substrate. If located within an internal layer (i.e., beneath the surface) of the substrate, a circuit device can be thermally connected to the heatspreader through elongated solder bumps, for example, longer solder bumps of a staggered solder bump array. The heatspreader can be thermally connected to a heat exchanger to dissipate the heat into the environment. Functional connectivity in this case is meant to specify thermal conductivity, which, in the simplest case, may be through vias or folded edge extensions.

In view of the above, notable advantages of the invention include heat absorption from a circuit device through its electrical ground connections, rapid heat removal from the circuit device and the surrounding vicinity with a fluid, enhanced heat transfer as a result of the fluid being contained and flowing within microchannels, and a light-weight design with high rigidity. In addition, because the heatspreader is part of the ground plane of the circuit board, current in the heatspreader can be used to drive electroosmotic flow of the coolant through the microchannels.

Other objects and advantages of this invention will be better appreciated from the following detailed description.

### BRIEF DESCRIPTION OF THE DRAWINGS

FIG. 1 schematically shows a ball grid array (BGA) package on a circuit board substrate and electrically connected with ground connections to a sealed fluid-filled heatspreader, which is located at a surface of the substrate and forms part of the ground plane of the substrate in accordance with a first embodiment of the invention.

FIG. 2A schematically shows a BGA package on a circuit board substrate and a sealed fluid-filled heatspreader located at a surface of the substrate and forming part of the ground plane of the substrate, wherein ground connections of the package are electrically connected to an extension of the heatspreader that is separated from surface areas of the substrate containing power and signal traces in accordance with a second embodiment of the invention.

FIG. 2B is a fragmentary top view of FIG. 2A, with the package represented in phantom to show the region containing the ground, power, and signal connections between the package, the heatspreader, and power/signal traces on the surface of the substrate.

FIG. 3 schematically shows a BGA package on a circuit board substrate and a sealed fluid-filled heatspreader located beneath a surface of the substrate and forming part of the ground plane of the substrate, wherein the package has a staggered array of solder bumps and the package are electrically connected to the heatspreader through longer solder bumps that extend through an outer layer of the substrate in accordance with a third embodiment of the invention.

FIG. 4 is similar to FIG. 3, but further includes a second BGA package on an opposite surface of the circuit board substrate and electrically connected to the heatspreader through longer solder bumps that extend through an outer layer of the substrate in accordance with a fourth embodiment of the invention.

FIG. 5 is similar to FIG. 3, but further shows the heatspreader as having an extension that protrudes from the circuit board substrate, and fins on the extension to promote heat transfer from the package to the environment in accordance with a fifth embodiment of the invention.

FIG. 6 is similar to FIG. 3, but further shows the heatspreader as having two extensions that protrude from and wrap around an edge of the circuit board substrate, and fins on one of the extensions to promote heat transfer from the package to the environment in accordance with a sixth embodiment of the invention.

### DETAILED DESCRIPTION OF THE INVENTION

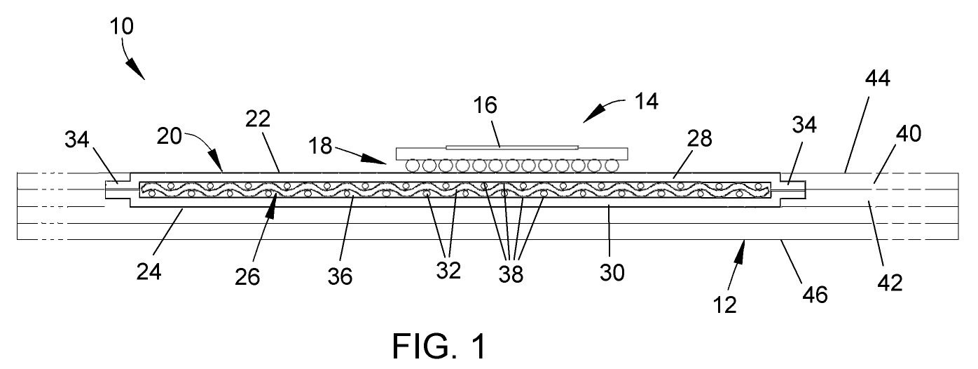

FIGS. 1 through 6 depict multiple configurations of heatspreaders in accordance with various embodiments of this invention. For convenience, consistent reference numbers are used to identify functionally similar structures throughout these Figures.

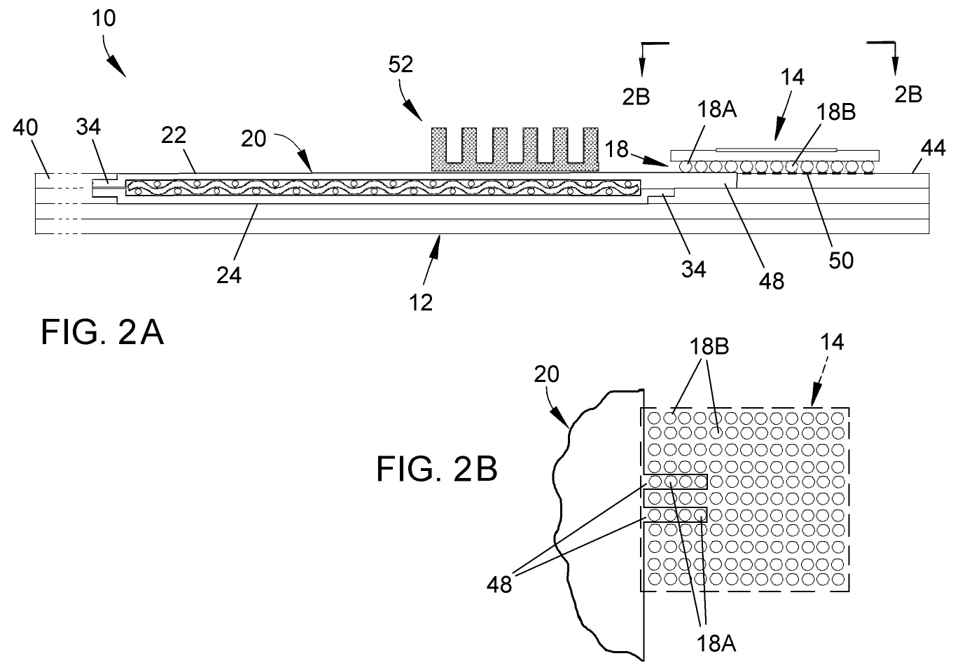

The present invention is represented in FIGS. 1 through 6 as a heatspreader 20 that also serves as part of the ground plane of a circuit board assembly 10. As described in more detail below, the heatspreader 20 is adapted for dissipating heat from electronic components mounted to the circuit board substrate 12, which may be a printed circuit board (PCB) or another suitable substrate. The electronic components may include various devices, the example shown in the Figures being a BGA package 14 carrying an IC die 16 and attached to the substrate 12 with solder connections 18 (only one row of which is visible in FIG. 1). The heatspreader 20 is particularly beneficial if the package 14 has a high power density. The heatspreader 20 is integrated into the circuit board substrate 12 to enable the heatspreader 20 to simultaneously function as a ground plane in the power and ground buses. Heat exchange between the package 14 and heatspreader 20 is through ground connections of the package 14, which in FIG. 1 are the visible solder connections 18 contacting the upper/exposed surface 22 of the heatspreader 20. As such, additional electrical connections (e.g., 18B in FIG. 2) are necessary to electrically connect the package 14 to power and signal traces (e.g., 50 in FIG. 2) on the substrate 12. For other types of electronic components, additional packaging may be omitted and solder bumps on an IC die may be directly bonded to the heatspreader 20.

As shown in FIG. 1, the heatspreader 20 is a self-contained, closed-loop, fluid-cooling device having a composite laminate construction, in which a relatively pliant screen or mesh 26 is sandwiched between two foils or plates 28 and 30 that are substantially parallel to each other. The mesh 26 is represented as being composed of individual strands 32 that are woven together, generally transverse to each other and conventionally referred to as warp and weft strands 32. The mesh 26 and plates 28 and 30 are preferably formed of materials having physically and chemically compatible properties, including materials having the same composition, though various material combinations are possible. For example, individual strands 32 of the mesh 26 can be formed by an individual wire, braided wires, bundled wires, etc., of copper, silver, aluminum, carbon, or alloys thereof, and the plates 28 and 30 can be formed of the same or similar materials. As discussed below, heat transfer occurs by conduction through the plates 28 and 30 and mesh 26, such that preferred materials for these components are thermally conductive, though the use of other materials including polymeric and nonmetallic materials is also foreseeable. Suitable thicknesses for the plates 28 and 30 and mesh 26, suitable cross-sectional shapes and dimensions for the mesh strands 32, and suitable weaves (including strands per inch) for the mesh 26 may depend on the particular application and the materials from which these components are formed.

As evident from FIG. 1, peripheral edge portions 34 of both plates 28 and 30 are preferably raised relative to the remainder of the plates 28 and 30, such as by embossing, to form a relief in each plate 28 and 30 that promotes their rigidity and further defines a continuous peripheral surface at which the plates 28 and 30 can be bonded to each other, such as with a solder alloy, braze alloy, adhesive, etc. With the plates 28 and 30 laminated together, the reliefs define a cavity 36 between the plates 28 and 30 that contains the cooling fluid of the heatspreader 20. Additional embossing can be performed on one or both plates 28 and 30 to define within the cavity 36 a channel system (not shown) between the plates 28 and 30, by which particular flow routes can be established within the heatspreader 20. Three-dimensional structures formed by such additional embossing have the further advantage of increasing the mechanical stability of the heatspreader 20.

As evident from FIG. 1, the mesh 26 within the cavity 36 may have approximately the same thickness as the height of the cavity 36 (as measured in the direction normal to the surface 22 of the plate 28). The peaks 38 projecting from both sides of the mesh 26 are preferably bonded, such as by soldering or brazing, to the plates 28 and 30 to establish a highly-conductive thermal contact between the mesh 26 and both plates 28 and 30. Bonding also serves to cross-link the plates 28 and 30, which resists any shearing forces to which the plates 28 and 30 are subjected and contributes additional mechanical stability and rigidity to the heatspreader 20. The warp and weft strands 32 of the mesh 26 form interstices that are more or less freely penetrable by any fluid, yet define tortuous paths that avoid laminar flow conditions within the cavity 36 that would reduce the heat transfer rate between the cooling fluid, the plates 28 and 30, and the mesh 26.

As generally known in the art, suitable coolant fluids include liquids such as water, mineral spirits/oils, alcohols, and fluorocarbonate derivatives, though various other fluids could also be used, including air, vapor, etc., depending on the required temperature range of operation. For example, in extremely cold environments, a fluid with lower viscosity is a better choice than in extremely hot environments. Various other parameters for choosing a cooling fluid exist and are well known, and therefore will not be discussed in any further detail here.

As evident from FIG. 1, the heatspreader 20 is self-contained with the cooling fluid being hermetically sealed within the cavity 36, such that cooling of the package 14 is achieved by providing a thermal conductive path between the package 14 with one of the plates 28/30 (plate 28 in the embodiment of FIG. 1). With the plate 28 in thermal contact with the package 14 as shown in FIG. 1, heat transfer from the package 14 is through the ground connections 18 and into the plate 28, the cavity 36 containing the mesh 26 and fluid, and the plate 28, which together cooperate to conduct heat away from the package 14, for example, to an edge (not shown) of the circuit board substrate 12. More particularly, heat transfer through the heatspreader 20 is by thermal conduction through the plate 28, mesh 26, and plate 30, and by convention between the plate 28 and the cooling fluid and between the cooling fluid and the plate 30, as well as convection through the cooling fluid from the plate 28 to the mesh 26 and convection through the cooling fluid from the mesh 26 to the plate 30. Accordingly, heat transfer is generally in a direction parallel to the plane of the heatspreader 20, and the fluid acts as a secondary heat absorbent and a thermal transport media capable of transporting thermal energy to the mesh 26 at a distance from the plate 28 nearest the heat source (the BGA package 14).

The cooling fluid may be recirculated through the cavity 36 with a pump (not shown) mounted on the substrate 12 or external to the circuit board assembly 10. A wide variety of pumps are possible and suitable for use in the heatspreader 20, and the choice of which will be primarily dependent on the specific application since pressure and noise requirements need to be taken into consideration. Notable but nonlimiting examples of suitable pump types include centrifugal, positive displacement, rotary, and osmotic pumps that are commercially available and have been used in prior cooling systems for electronic components.

Because the cooling fluid assists the plates 28 and 30 in conducting heat from the package 14, the coefficient of thermal conductance of the material(s) used to form the plates 28 and 30 is less important than in structures that rely on passive heat transfer. As such, a wider variety of materials could be used to form the heatspreader 20 and its individual components. Moreover, because the heatspreader 20 is hollow, the total amount of material used is substantially lower than in a comparable solid structure, resulting in reduced material costs for manufacturing the heatspreader 20. A related issue is the mechanical stability of the heatspreader 20. Hollow structures generally exhibit only a minor reduction in rigidity as compared to a solid body of the same dimensions. The rigidity of the heatspreader 20 is promoted as a result of the peripheral edge portions 34 of the plates 28 and 30 being bonded together, as well as bonding of the mesh 26 to both plates 28 and 30. Consequently, the heatspreader 20 can be much lighter but yet nearly as strong and rigid as a solid heatspreader of comparable size.

In the embodiment of FIG. 1, the heatspreader 20 is shown embedded in a surface layer 40 and an immediately adjacent subsurface layer 42 of the circuit board substrate 12, such that the surface 22 of the heatspreader 20 is generally flush with the substrate surface 44 at which the package 14 is mounted. The opposite surface 24 of the heatspreader 20 is buried within the substrate 12, and not exposed at the surface 46 of the substrate 12 opposite the surface 44.

In FIG. 2A, the solder connections 18 of the BGA package 14 are shown as being arranged as a group of ground solder connections 18A and signal and power solder connections 18B. The ground solder connections 18A directly contact an extension 48 of the heatspreader 20 that is formed by the plate 28 and contiguous with the surface 22 of the heatspreader 20. The extension 48 extends beneath a limited portion of the package 14 corresponding to the ground solder connections 18A, but not beneath portions of the package 14 where the signal/power solder connections 18B and their traces 50 are located. As in FIG. 1, the surface 22 of the heatspreader 20 is approximately flush with the substrate surface 44, such that the ground and power/signal solder connections 18A and 18B have approximately equal heights (lengths perpendicular to the plane of the substrate 12). The heatspreader 20 is further shown as including fins 52 that project above the surface 44 of the substrate 12 and promote convective and radiative heat transfer to the surrounding environment.

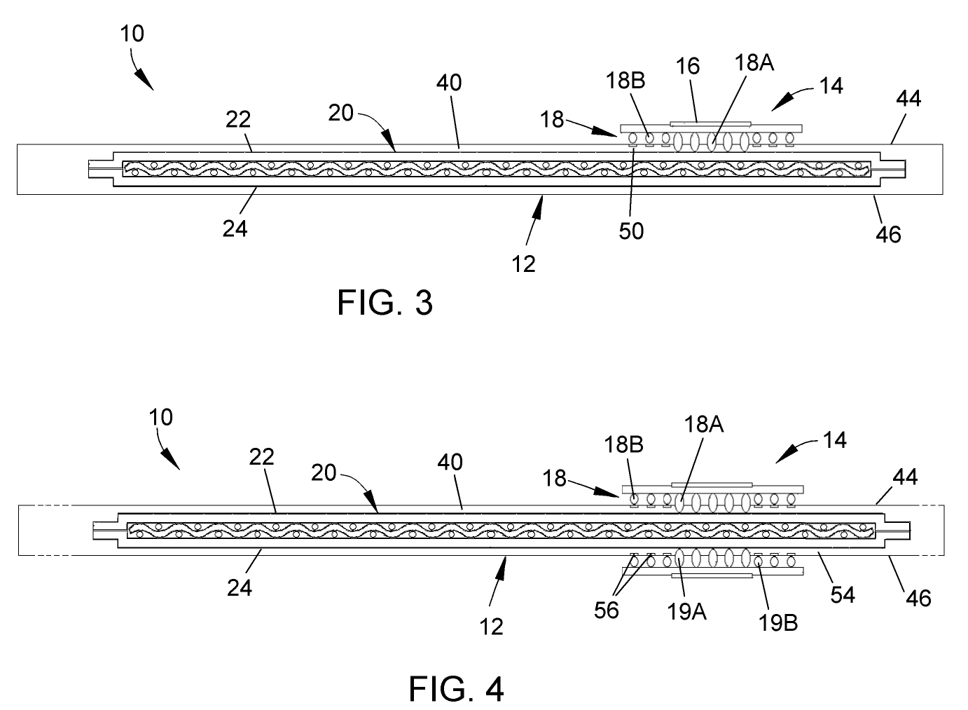

As represented in FIG. 2B, the extension 48 of the heatspreader 20 is one of multiple finger-like extensions 48 that collect heat from the ground solder connections 18A. The extensions 48 are preferably interdigitated with the signal/power solder connections 18B and their traces 50 (not shown) to avoid electrical shorting between the ground plane, power, and signal lines of the substrate 12. The embodiment of FIG. 1 will also typically require physical separation between the heatspreader 20 and the signal/power solder connections 18B and their traces 50, depending on the manner in which the package 14 is electrically connected to its power and signal traces on the substrate 12. The embodiments of FIGS. 3 through 6 are capable of avoiding this limitation.

FIG. 3 shows the integration of the heatspreader 20 into subsurface (internal) layers of the circuit board substrate 12, such that both surfaces 22 and 24 of the heatspreader 20 are embedded in the substrate 12 and the surface 22 nearest the heat source (package 14) is beneath the outer surface 44 of the substrate 12. The solder connections 18 of the BGA package 14 are shown as being vertically staggered, with the ground solder connections 18A being slightly elongated compared to the signal/power solder connections 18B in order to penetrate the surface layer 40 of the circuit board substrate 12. An advantage of this configuration is that the shape of the heatspreader 20 in the plane of the substrate 12 can be relatively simple, since there is no need to meander around the signal and power traces 50 to avoid electrical shorting with the ground plane. As such, the signal and power traces 50 can be located on the outer surface 44 of the substrate 12 between the package 14 and heatspreader 20, and the package 14 can lie entirely above the heatspreader 20. Furthermore, the ground solder connections 18A are situated directly beneath the IC die 16 for optimal heat transfer to the heatspreader 20.

The embodiment of FIG. 4 is similar to that of FIG. 3, but further includes a second BGA package 15 on the lower surface 46 of the circuit board substrate 12. As in FIG. 3, the package 15 is electrically connected to the heatspreader 20 through longer ground solder bumps 19A that extend through an outer layer 54 of the substrate 12, while shorter signal/power solder bumps 19B contact signal and power traces 56 located on the substrate's lower surface 46. The packages 14 and 15 can mounted to the substrate 12 in a clamshell configuration.

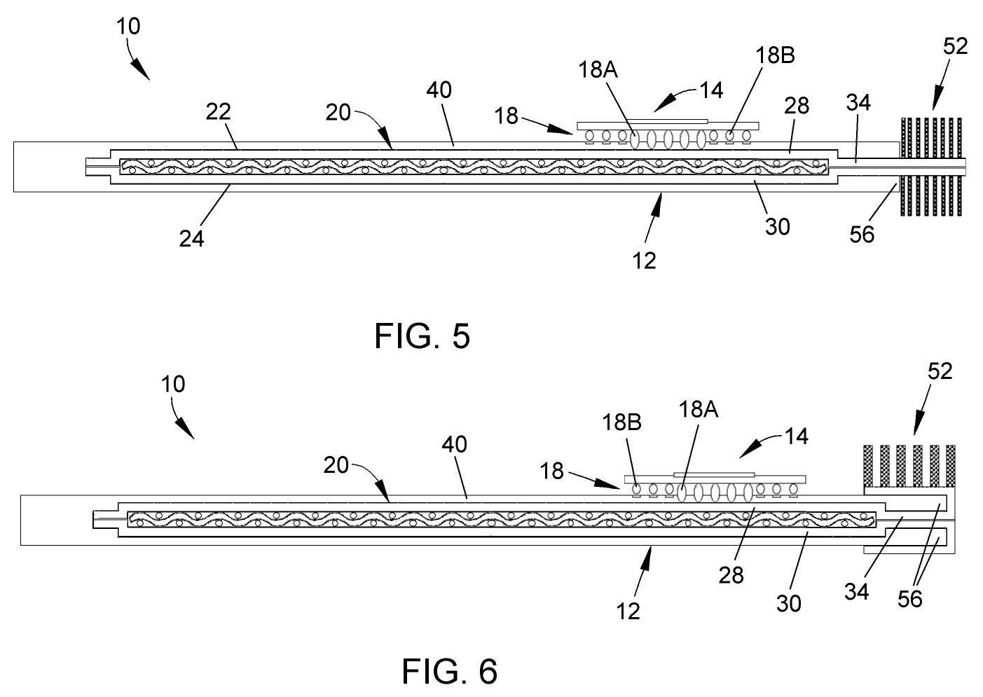

In the embodiment of FIG. 5, a pair of the peripheral edge portions 34 of the plates 28 and 30 are shown elongated and protruding beyond an edge 56 of the substrate 12, providing a location for two oppositely-disposed sets of fins 52 that promote convection heat transfer to the environment.

Finally, FIG. 6 shows a configuration in which a pair of the peripheral edge portions 34 of the plates 28 and 30 are elongated and wrapped around an edge 56 of the circuit board substrate 12, with fins 52 provided on one of the edge portions 34. With this configuration, the heatspreader 20 and its fins 52 do not significantly increase the length of the circuit board assembly 10 beyond that of the substrate 12.

While the invention has been described in terms of specific embodiments, it is apparent that other forms could be adopted by one skilled in the art. For example, additional embodiments could be constructed that differ in appearance and construction from the embodiments shown in the Figures, and appropriate materials could be substituted for those noted. Therefore, the scope of the invention is to be limited only by the following claims.

1. A circuit board assembly comprising:
a circuit board substrate having at least one circuit device on at least a first surface thereof and an electrical ground plane, the circuit device having a first set of solder connections electrically connected to the electrical ground plane and a second set of solder connections electrically connected to power and signal traces on the first surface of the substrate; and
a heatspreader embedded in the substrate, the heatspreader defining an electrical element of the electrical ground plane and being electrically connected to the first set of solder connections, the heatspreader comprising a plate-mesh-plate laminate that defines a cavity and a fluid within the cavity for transferring heat from the circuit device.

2. The circuit board assembly according to claim 1, wherein the heatspreader comprises:
first and second plates arranged substantially in parallel and bonded together to define the cavity therebetween and seal the fluid within the cavity, the first plate defining an outer surface of the heatspreader and being adapted for thermal contact with the circuit device; and
a mesh disposed within the cavity and lying in a plane substantially parallel to the first and second plates, the mesh comprising interwoven strands bonded to the first and second plates, the interwoven strands defining interstices therebetween through which the fluid within the cavity is able to flow.

3. The circuit board assembly according to claim 1, wherein the heatspreader has a surface exposed at the first surface of the substrate.

4. The circuit board assembly according to claim 3, wherein the surface of the heatspreader is substantially flush with the first surface of the substrate.

5. The circuit board assembly according to claim 3, wherein the heatspreader has a peripheral edge portion contiguous with the surface thereof, the peripheral edge portion being exposed at the first surface of the substrate and defining extensions that physically contact the first set of solder connections.

6. The circuit board assembly according to claim 5, wherein the extensions are interdigitated with the power and signal traces of the circuit device.

7. The circuit board assembly according to claim 3, wherein the first and second sets of solder connections have approximately equal heights.

8. The circuit board assembly according to claim 1, wherein the heatspreader has oppositely-disposed surfaces that are embedded in the substrate so as not to be exposed at the first surface of the substrate or an oppositely-disposed second surface of the substrate.

9. The circuit board assembly according to claim 8, wherein the first set of solder connections physically contact the heatspreader, are longer than the second set of solder connections, and extend through an outer layer of the substrate.

10. The circuit board assembly according to claim 8, further comprising a second circuit device on a second surface of the substrate oppositely disposed from the first surface of the substrate, the second circuit device having a first set of solder connections electrically and physically connected to the heatspreader and a second set of solder connections electrically connected to power and signal traces on the second surface of the substrate.

11. The circuit board assembly according to claim 8, wherein the heatspreader has a peripheral edge portion that protrudes from an edge of the substrate.

12. The circuit board assembly according to claim 11, further comprising fins on the peripheral edge portion, the fins defining a convection heat transfer interface of the heatspreader to an environment surrounding the assembly.

13. The circuit board assembly according to claim 11, wherein the peripheral edge portion wraps around the edge of the substrate and covers a portion of at least the first surface of the substrate.

14. A method of combining an electrical ground plane of a circuit board substrate with heat dissipation from a circuit device on a first surface of the substrate, the method comprising fabricating the substrate to have an embedded heatspreader comprising a plate-mesh-plate laminate filled with coolant fluid.

15. A method according to claim 14, wherein the heatspreader is embedded so as to be exposed at the first surface of the substrate.

16. The method according to claim 15, wherein the heatspreader is fabricated to have extensions that are interdigitated with power and signal traces on the first surface of the substrate, the extensions being physically and electrical connected to ground connections of the circuit device.

17. A method according to claim 14, wherein the heatspreader is embedded so as not to be exposed at the first surface of the substrate.

18. The method according to claim 17, wherein the heatspreader is physically and electrical connected to ground connections of the circuit device but not to power and signal connections of the circuit device, and the ground connections are longer than the power and signal connections.

19. The method according to claim 17, wherein the heatspreader is fabricated to have a peripheral edge portion that extends past an edge of the substrate and defines a convection heat transfer interface.

20. The method according to claim 19, wherein the peripheral edge portion is wrapped around the substrate and covers a portion of at least the first surface of the substrate.
